(19) United States
(12) Patent Application Publication
(10) Pub. No.: US 2009/0053125 A1
(43) Pub. Date: Feb. 26, 2009

(54) Stabilizing 4H Polytype During Sublimation Growth Of SiC Single Crystals

(75) Inventors: Avinash K. Gupta, Basking Ridge, NJ (US); Thomas E. Anderson, Convent Station, NJ (US); Ping Wu, Warren, NJ (US); Ilya Zwieback, Washington Township, NJ (US)

Correspondence Address: THE WEBB LAW FIRM, P.C., 700 KOPPERS BUILDING, 436 SEVENTH AVENUE, PITTSBURGH, PA, 15219, US

(73) Assignee: Il-VI Incorporated, Saxonburg, PA (US)

(21) Appl. No.: 12/194,066

(22) Filed: Aug. 19, 2008

Related U.S. Application Data
(60) Provisional application No. 60/956,789, filed on Aug. 20, 2007.

(51) Int. Cl. C01B 31/36; C30B 23/06

(52) U.S. Cl. 423/346; 117/84

(57) ABSTRACT

A SiC single crystal is grown by physical vapor transport (PVT) in a graphite growth chamber, the interior of which is charged with a SiC source material and a SiC single crystal seed in spaced relation. During PVT growth of the SiC single crystal, the growth chamber further includes Ce. The SiC single crystal grows on the SiC single crystal seed in response to heating the interior of the growth chamber to a growth temperature and in the presence of a temperature gradient in the growth chamber whereupon the temperature of the SiC single crystal seed is lower than the temperature of the SiC source material. The Ce can include either Ce silicide or Ce carbide.

### CROSS REFERENCE TO RELATED APPLICATION

This application claims priority from U.S. Provisional Patent Application No. 60/956,789, filed Aug. 20, 2007, which is incorporated herein by reference.

### BACKGROUND OF THE INVENTION

1. Field of the Invention

The present invention relates to the field of bulk growth of silicon carbide (SiC) single crystals by sublimation using the technique of Physical Vapor Transport (PVT) and, more specifically, to the sublimation growth of SiC single crystals of the 4H polytype.

2. Description of Related Art

Wafers of SiC of the 4H polytype (hereafter 4H-SiC) serve as lattice-matched substrates to grow epitaxial layers of SiC and GaN, which are used for fabrication of SiC- and GaN-based semiconductor devices utilized in power and RF electronic applications. Large 4H-SiC single crystals are commonly grown by sublimation using a technique called (PVT).

With reference to FIG. 1, PVT growth is typically carried out in a graphite growth crucible 1 sealed with a graphite lid 2 and loaded with a polycrystalline SiC source 3 and a monocrystalline SiC seed crystal 4. Generally, source 3 is disposed at the bottom of crucible 1 and seed crystal 4 at the top of crucible 1. Seed crystal 4 is often mounted directly to graphite lid 2 using adhesives or mechanical means (not shown). However, this is not to be construed as limiting the invention since seed crystal 4 can be mounted to graphite lid 2 by way of a graphite seed-holder disposed between seed crystal 4 and lid 2.

Loaded crucible 1 is placed inside a growth chamber 6 where it is surrounded by thermal insulation 7, desirably made of fibrous graphite foam.

RF heating is commonly used in SiC sublimation growth for heating crucible 1 to growth temperatures. RF heating is typically accomplished by way of an RF coil 8 placed outside chamber 6, which comprises water-cooled walls made of fused silica. The use of electrically nonconductive fused silica permits electromagnetic field generated by RF coil 8 to penetrate inside chamber 6 and to couple with the graphite that forms crucible 1, which serves as an efficient RF susceptor. The use of RF coil 8 to heat crucible 1 and, hence, source 3 and seed crystal 4 to crystal growth temperatures is not to be construed as limiting the invention since it is envisioned that other suitable and/or desirable means for heating source 3 and seed crystal 4 to a suitable temperature for growing a SiC single crystal boule 5 on seed crystal 4 by sublimation can be used, such as resistive heating.

During PVT growth, crucible 1 is heated to the growth temperature, which is generally between 2000° C. and 2400° C. The temperatures of source 3 and seed crystal 4 can be monitored using optical pyrometers, which can be aimed through bottom and top openings 10 in thermal insulation 7.

RF coil 8 is positioned with respect to crucible 1 in such a fashion that the temperature of source 3 is maintained higher than that of seed crystal 4. Desirably, the difference between the temperatures of source 3 and seed crystal 4 is between 10° C. and 200° C.

Upon reaching a suitably high temperature, source 3 vaporizes and fills crucible 1 with volatile molecular species of Si₂C, SiC₂ and Si. The temperature difference between source 3 and seed crystal 4 forces the vapors to migrate and precipitate on seed crystal 4 forming SiC single crystal boule 5. In order to control the growth rate and ensure the formation of SiC single crystal boule 5 having a sufficiently high quality, PVT growth is carried out under a pressure of inert gas, such as argon or helium, desirably between 1 and 200 Torr, and more desirably, between 1 and 100 Torr.

Polytypism or the existence of multiple crystalline modifications (polytypes) is a characteristic feature of SiC. SiC polytypes are distinguished from each other by their atomic stacking sequences. Two hexagonal polytypes of SiC, 6H and 4H, are of most importance for electronic applications. These polytypes can be viewed as layered structures; that is in the direction of the hexagonal c-axis, these polytypes are stacked of identical layers of Si—C hexagons, which are shifted and turned with respect to each other. Depending on their mutual alignment, these bi-atomic layers are commonly labeled as A, B and C. In the 4H polytype, the stacking sequence is ABAC, ABAC, while in the 6H polytype—ABCACB, ABCACB. In addition to the hexagonal polytypes, a number of other SiC polytypes exist, including 15R, which is stacked of 15 layers and belongs to the rhombohedral symmetry group.

In the conditions of conventional PVT sublimation growth of SiC, the 6H polytype is stable. That is, SiC crystals grown on 6H seeds are typically of the same polytype as the seed, and the presence of other polytypes in the bulk of 6H boules is very rare. However, stable PVT growth of 4H-SiC crystals is more difficult, and appearances of foreign polytypes such as 6H or 15R in the bulk of the 4H boules are quite common. Formation of a foreign polytype inclusion can occur at any stage of the 4H growth process. Such polytype instability leads to crude crystal defects and reduces the yield of high-quality 4H-SiC substrates.

Instability of the 4H polytype during conventional PVT growth can be caused by uncontrollable perturbations of the growth conditions, and it is commonly believed that the 4H polytype is more “sensitive” to such perturbations than the 6H polytype. Although there is no consensus regarding the mechanism of polytype change and the nature of the aforementioned growth perturbations, temperature and pressure fluctuations are often invoked as the most understandable root causes.

The following exemplifies how temperature fluctuations can cause the appearance of foreign polytype(s). While the under-saturated vapor near the source 3 includes Si, Si₂C and SiC₂ volatile molecules, more complex Si—C molecular associates can exist in the supersaturated vapor in the vicinity of the growth interface of SiC single crystal boule 5. These unstable associates are commonly called “meta-stable” or “under-critical” nuclei. The crystal structure of such nuclei should resemble the most thermodynamically favorable polytype. Based on thermodynamic and kinetic considerations, such meta-stable nuclei should exist for very short time periods. Nevertheless, there is a non-zero probability for adsorption of some of them on the growth interface of SiC single crystal boule 5. Temperature fluctuations in the space near the growth interface of SiC single crystal boule 5 cause fluctuations in the supersaturation of the vapor. This, in turn, can cause the formation of other than 4H meta-stable nuclei in the vapor phase and their absorption on the growth interface of SiC single crystal boule 5. This may lead to the appearance of foreign polytypes in the growing SiC single crystal boule 5.

Other disturbances, such as contamination of the growth interface of SiC single crystal boule 5, can also lead to polytype instability. The most common contamination of SiC single crystal boule 5 growth interface is by carbon particles liberated from the graphite growth crucible 1 and/or carbonized SiC source.

How to improve the stability of the 4H polytype during growth has been discussed in the prior art. The commonly accepted practical recommendations for stable 4H growth include: (a) growing on the carbon face of the seed; (b) growing on the seed off-cut by several degrees from the c-plane; (c) choosing proper growth conditions, especially proper temperature; and (d) avoiding growth disturbances. While these recommendations are widely used today and their implementation has led to some improvements in the 4H polytype stability, these recommendations do not completely eliminate the appearance of foreign polytypes in PVT-grown 4H-SiC boules.

It would, therefore, be desirable to provide a system and method for growing SiC single crystals that further reduces or completely avoids the formation of foreign polytypes in PVT-grown 4H-SiC boules.

### SUMMARY OF THE INVENTION

While the exact phenomena behind polytype stabilization are unknown, it is believed that they may stem from at least one of the following: the stabilizing impurity affects equilibrium in the vapor phase, leading to dissociation of meta-stable nuclei of foreign polytypes; the stabilizing impurity is adsorbed on the growth interface and stabilizes the atomic growth mechanism which favors the 4H stacking sequence; or the stabilizing impurity is dissolved in the bulk of the growing crystal and changes its bulk properties making the 4H polytype energetically more favorable than other polytypes.

The present inventors have observed that the stability of the 4H polytype during SiC sublimation growth improves significantly when cerium (Ce) or a Ce compound is added to the growth charge, i.e., Ce is added to the polycrystalline SiC source 3.

Accordingly, the present invention is an improved PVT sublimation growth system and method that incorporates a polytype stabilizing additive to the polycrystalline SiC growth charge for the purpose of improving the stability of the 4H polytype during growth. The polytype stabilizing additive can be Ce or one or more Ce compounds, such as silicides and/or carbides. The Ce compound is preferably added to the growth charge in amounts between 0.1-5.0 percent weight of the polycrystalline SiC source material. The Ce compound additive can be placed directly in the bulk of the SiC source or can be disposed inside the growth crucible separately from the SiC source, for example, in a graphite capsule.

The present invention improves the stability of the 4H polytype during growth, dramatically reduces the presence of foreign polytype inclusions in the bulk of 4H-SiC boules and yields high-quality 4H-SiC material. The described growth process can be used to grow both undoped and doped 4H-SiC single crystals, including those doped, without limitation, with nitrogen or vanadium.

More specifically, the present invention is a SiC single crystal grown by physical vapor transport (PVT) in a graphite growth chamber, the interior of which is charged with a SiC source material and a SiC single crystal seed in spaced relation, wherein during PVT growth of the SiC single crystal the growth chamber further includes Ce and the SiC single crystal grows on the SiC single crystal seed in response to heating the interior of the growth chamber to a growth temperature and in the presence of a temperature gradient in the growth chamber whereupon the temperature of the SiC single crystal seed is lower than the temperature of the SiC source material.

The SiC single crystal can further comprise either vanadium or nitrogen.

The Ce can comprise either Ce silicide or Ce carbide.

The growth temperature can be between 2000° C. and 2400° C. The temperature gradient can be between 10° C. and 200° C.

The invention is also a method of physical vapor transport growing a SiC single crystal. The method includes: (a) providing a growth chamber charged with SiC source material and a SiC single crystal seed in spaced relation; (b) providing Ce in the growth chamber, wherein the Ce is either mixed with the SiC source material in the growth chamber or is contained in a capsule in the growth chamber, wherein the capsule has a capillary that extends between the interior thereof and the exterior thereof; and (c) heating the SiC source material, the SiC single crystal seed and the Ce to a growth temperature whereupon a temperature gradient forms in the growth chamber that causes the SiC source material and the Ce to sublimate, the temperature gradient causes the sublimated SiC source material to be transported to the SiC single crystal seed where it precipitates on the SiC single crystal seed to form a SiC single crystal on the SiC single crystal seed.

The sublimated Ce promotes the formation of a 4H polytype in the SiC single crystal.

The capsule can be made from graphite.

The Ce can comprise 0.1%-5.0% weight of the SiC source material.

Step (c) can occur in the presence of a gas at a pressure between 1 and 200 Torr. The gas can comprise an inert gas. The inert gas can be either argon or helium.

The gas can further comprise nitrogen.

Vanadium can be included in the SiC source material.

The Ce can be comprised of either Ce silicide or Ce carbide.

The temperature gradient can be between 10° C. and 200° C. The growth temperature can be between 2000° C. and 2400° C.

### BRIEF DESCRIPTION OF THE DRAWINGS

FIG. 1 is a cross-sectional schematic view of a physical vapor transport (PVT) growth system for growing a SiC single crystal on a SiC single crystal seed;

FIG. 2A is a photograph of an N-type 4H-SiC boule grown by PVT process using CeSi₂ additive;

FIG. 2B is a dislocation density map of an N-type 4H-SiC wafer taken from the N-type 4H-SiC boule show in FIG. 2A;

FIG. 3A is a photograph of a vanadium-doped semi-insulating 4H-SiC boule grown by PVT process with CeSi₂ additive;

FIG. 3B is a micropipe density (MPD) map of a vanadium-doped semi-insulating wafer taken from the vanadium-doped semi-insulating 4H-SiC boule of FIG. 3A, wherein the wafer has a MPD=3 cm⁻²; and

FIG. 4 is a graph of axial distribution of resistivity in a vanadium-doped semi-insulating wafer taken from the vanadium-doped semi-insulating 4H-SiC boule of FIG. 3A.

### DETAILED DESCRIPTION OF THE INVENTION

The present invention will be described with reference to the accompanying figures where like reference number correspond to like elements.

The chemical composition of rare earth silicides and rare earth carbides can be expressed by the generalized formulas RₓSi_{y} and RₓC_{y}, respectively, where R is the rare earth element. The following stoichiometric formulas are common for the rare earth silicides: RSi₂, R₂Si₃ and R₃Si₄. For the rare earth carbides, the following formulas are typical: R₃C, R₂C₃, RC and RC₂.

In the carbon-rich conditions of SiC single crystal boule 5 PVT growth, silicides and (lower) carbides can undergo chemical transformations leading to the appearance of stable (higher) carbides. An example of such reactions for Ce include:

CeSi₂+4C→2SiC+CeC₂

Ce₂C₃+C→2CeC₂

A majority of the rare earth silicides and carbides have high melting points, typically above 1500° C. The atomic radii of the rare earths are typically larger than the covalent radii of Si and C in the lattice of SiC. Therefore, it is believed that rare earth elements have a low solubility in SiC.

The vapor pressure of the rare earth elements over their silicides or carbides is unknown. However, based on the low volatility of the elemental rare earth elements, it is believed that the vapor pressure over the rare earth silicides and carbides is sufficiently low to prevent evaporation losses from the growth crucible.

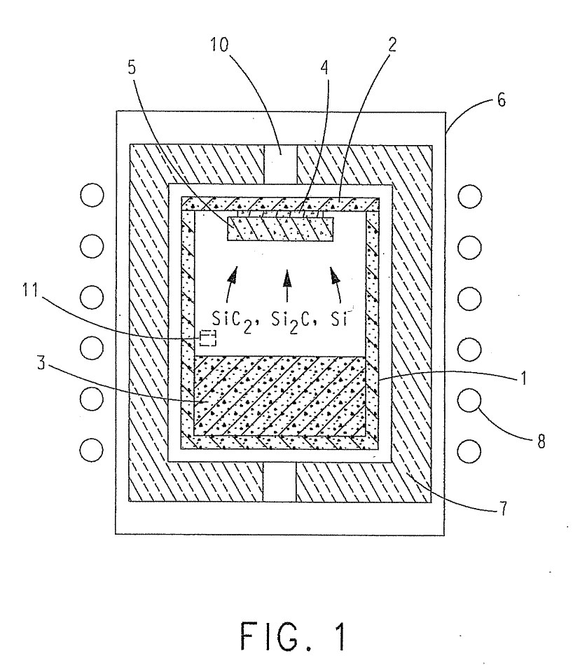

In order to achieve the desired effect of 4H polytype stabilization, a Ce compound is added to the SiC growth charge in concentrations between 0.1-5.0 weight percent with respect to the weight of the SiC source 3. The Ce compound can be added (mixed) directly with the SiC source 3. Alternatively, the Ce compound can be included in a graphite capsule 11, shown in phantom in FIG. 1, which, in turn, is disposed inside the PVT growth crucible 1. When heated to the growth temperature of SiC single crystal boule 5, the Ce compound inside of graphite capsule 11 vaporizes and passes through a capillary in graphite capsule 11 into the interior of crucible 1 where it mixes with the vaporized SiC source 3 during the growth of the SiC single crystal boule 5.

The use of the Ce compound in the PVT growth of 4H-SiC single crystals yields 4H-SiC boules, whether nitrogen-doped (N-type), vanadium doped (semi-insulating) or nominally undoped, that contain fewer inclusions of foreign polytypes, such as 6H and 15R, than 4H-SiC single crystals grown without the Ce compound.

Table 1 shows the yield of nitrogen-doped (N-type) 4H crystals grown with and without the addition of CeSi₂ in crucible 1. In the SiC growth runs summarized in Table 1, Ce silicide (CeSi₂) was used as a polytype stabilizing additive. In growth runs performed with no CeSi₂ included in crucible 1, 4H-SiC single crystal boules containing foreign polytypes accounted for 38% of the performed growth runs (19 out of 50). In growth runs performed with CeSi₂ included in crucible 1, either in capsule 11 or mixed with the SiC source 3, the percentage of 4H-SiC single crystal containing foreign polytypes was reduced to 19%.

TABLE 1
Yield of nitrogen-doped N-type 4H—SiC crystals
grown with and without CeSi₂ additive

| Number of | | Boules with | % Boules with |
|---|---|---|---|
| Grown | Addition | Foreign | Foreign |
| Boules | of CeSi₂ | Polytype | Polytype |
| 50 | No | 19 | 38% |
| 36 | Yes | 7 | 19% |

Table 2 shows the yield of semi-insulating (vanadium-doped) 4H-SiC crystals grown with and without the addition of CeSi₂ in crucible 1. All vanadium-doped semi-insulating crystals grown without the addition of CeSi₂ in crucible 1 showed the presence of the 6H and/or 15R polytypes. With the addition of CeSi₂ in crucible 1, either in capsule 11 or mixed with the SiC source 3, only one out of fourteen boules (7%) had foreign polytype inclusions.

TABLE 2
Yield of vanadium-doped semi-insulating 4H—SiC
crystals grown with and without CeSi₂ additive

| Number of | | Boules with | % Boules with |
|---|---|---|---|
| Grown | Addition | Foreign | Foreign |
| Boules | of CeSi₂ | Polytype | Polytype |
| 5 | No | 5 | 100% |
| 14 | Yes | 1 | 7% |

Table 3 shows the yield of nominally undoped 4H-SiC crystals grown with and without the addition of CeSi₂ in crucible 1. One undoped boule grown without the addition of CeSi₂ exhibited almost complete conversion into 6H and 15R polytypes. Two undoped boules grown with the addition of CeSi₂ in crucible 1, either in capsule 11 or mixed with the SiC source 3, contained no foreign polytype inclusions.

TABLE 3
Yield of nominally undoped 4H—SiC crystals
grown with and without CeSi₂ additive

| Number of | | Boules with | % Boules with |
|---|---|---|---|
| Grown | Addition | Foreign | Foreign |
| Boules | of CeSi₂ | Polytype | Polytype |
| 1 | No | 1 | 100% |
| 2 | Yes | 0 | 0% |

The improved polytype stability leads to higher yields of high-quality 4H-SiC boules and, hence, to increased production of the high-quality commercial 4H-SiC wafers sliced from said boules.

Examples of practical realization of the invention will now be described with reference to FIG. 1.

Growth Runs of Two N-Type 4H-SiC Boules.

The growth of two N-type 4H-SiC single crystal boules was carried out in the PVT growth system shown in FIG. 1. For each boule, a sublimation source of pure SiC grain 0.5-2 mm in size and weighing 600 g was prepared and mixed with 1 g of a Ce silicide additive, namely Ce disilicide (CeSi₂) lumps about 1 mm in size. The mixture of SiC source 3 and CeSi₂ additive was disposed on the bottom of growth crucible 1. A SiC seed crystal 4 was prepared and attached to the lid 2 of crucible 1, as shown in FIG. 1. Each growth run was carried out in an argon atmosphere at a pressure of 10 Torr. In order to achieve nitrogen doping, a small flow of nitrogen was introduced into crucible 1. Crucible 1 was heated by RF coil 8 whereupon the temperatures of SiC seed crystal 4 and the mixture of CeSi₂ and SiC source 3 were brought to and maintained throughout the growth run at 2090° C. and 2160° C., respectively.

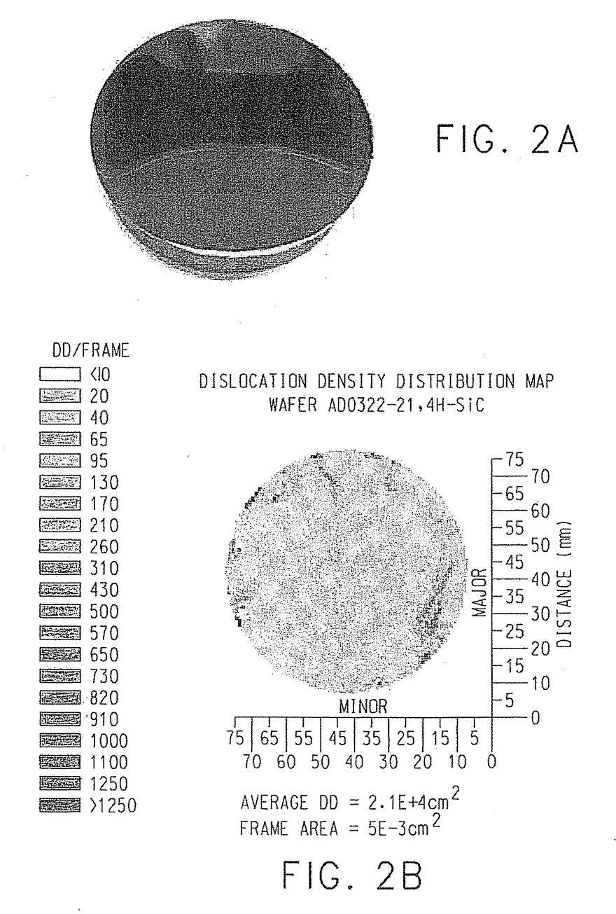

A photograph of one of the as-grown SiC single crystal boules 5 is shown in FIG. 2A. In n-type material, various polytypes have different colors. For instance, 6H has a dense green color, 4H has a light brown tint and 15R is yellow. Therefore, the presence of foreign polytypes in as-sawn wafers can be easily detected upon investigation under bright light. Such investigation of the wafers sliced from these two 4H-SiC single crystal boules revealed no evidence of foreign polytypes.

The presence of foreign polytypes in 4H crystals, even very small polytype inclusions, leads to the generation of dislocations and micropipes. Therefore, small polytype inclusions can be detected using wafer etching in molten KOH. To this end, upon etching, possible polytype inclusions are visible as clusters of micropipes or dislocations. FIG. 2B shows a dislocation density map obtained on one of the wafers sliced from one of the two grown 4H-SiC single crystal boules. The map shows no dislocation clusters. The overall dislocation density in this boule was quite low, about 2.1×10⁴ cm⁻², thus confirming that no formation of foreign polytypes occurred during growth.

The resistivity of wafers sliced from the two grown 4H-SiC single crystal boules was about 0.017 ohm-cm, which is typical for 4H-SiC crystals grown conventionally without silicide additives. This shows that the Ce silicide additives have no effect on the electrical properties of N-type nitrogen-doped 4H-SiC crystals.

Growth Runs of Two Semi-Insulating (Vanadium-Doped) 4H-SiC Boules.

The growth of two vanadium-doped 4H-SiC single crystal boules was carried out in the PVT growth system shown in FIG. 1. For each boule, a sublimation source of pure SiC grain 0.5 to 2 mm in size and weighing 600 g was prepared. In order to achieve semi-insulating properties in each 4H-SiC single crystal boule, the sublimation source included a proper amount of vanadium, e.g., without limitation, 200 ppmw and 1000 ppmw of vanadium, serving as a compensating dopant. Graphite capsule 11 having a 1 mm diameter capillary was prepared and loaded with 2 g of CeSi₂ lumps, about 1 mm in size. The silicide-containing capsule 11 was placed on the crucible bottom and covered with the SiC source 3. However, this is not to be construed in a limiting sense, since it is envisioned that capsule 11 can be placed in the bulk of SiC source 3 or on the surface of SiC source 3, as shown in phantom in FIG. 1.

A 3.00-inch diameter 4H-SiC seed crystal 4 was prepared and attached to lid 2 of crucible 1. The thus prepared crucible 1 was placed into growth chamber 6, which was then evacuated and filled with 10 Torr of pure helium. Crucible 1 was then heated by RF coil 8 whereupon the temperatures of SiC seed crystal 4 and SiC source 3 were brought to and maintained throughout the growth run at 2100° C. and 2150° C., respectively.

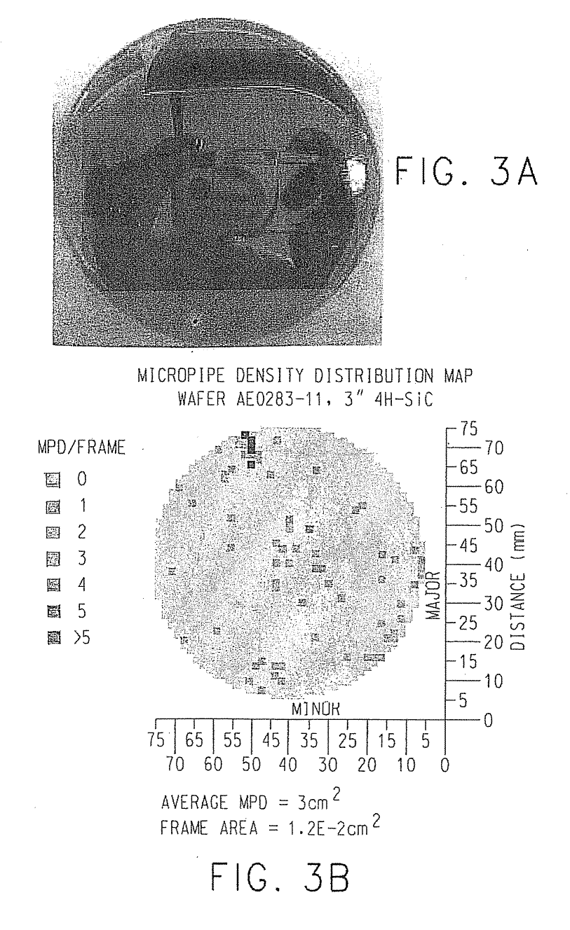

FIG. 3A shows a photograph of one of the as-grown semi-insulating 4H-SiC boules. In semi-insulating material, various polytypes have the same color, i.e., they are nearly colorless, and their presence cannot be detected upon investigation under bright light. However, foreign polytype can be found in semi-insulating 4H-SiC boules using x-ray diffractometry (Laue) or using Raman spectroscopy. However, both of these methods can probe only small areas of the wafer, about 1 mm². Therefore, these techniques cannot be relied upon for finding small polytype inclusions in large-diameter wafers.

The most practical method for finding polytype inclusions in semi-insulating 4H-SiC boules is by etching in molten KOH. Such etching makes polytype inclusions visible as clusters of micropipes or dislocations. FIG. 3B shows a micropipe density (MPD) map of a wafer sliced from one of the as-grown semi-insulating 4H-SiC boules produced by etching in molten KOH. The average MPD value in this wafer was 3 cm-2, thus indicating that no foreign polytype inclusions were present in the boule from which the wafer was sliced. A small micropipe cluster visible on the map at 11 o'clock is due to a slightly misoriented 4H edge grain.

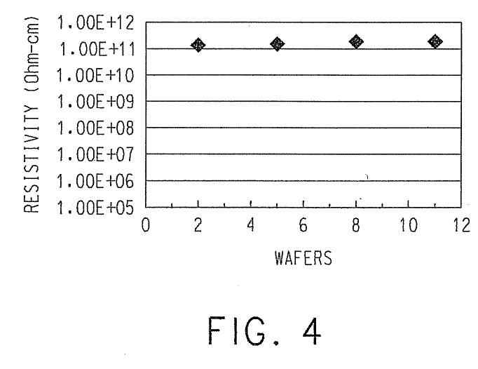

The resistivity of wafers sliced from one of the as-grown semi-insulating (vanadium-doped) 4H-SiC boules grown with CeSi₂ additive was measured. The measurements were carried out at room temperature and under normal room light. The axial distribution of resistivity of wafers sliced from this boule is shown in FIG. 4. As can be seen, the resistivity of the as-grown semi-insulating (vanadium-doped) 4H-SiC boules grown with CeSi₂ additive was between 10¹¹ and 10¹² ohm-cm. This is very similar to the resistivity of vanadium-doped 6H or 4H-SiC crystals grown conventionally. Thus, the presence of CeSi₂ in the charge does not affect electronic properties of the vanadium-doped semi-insulating 4H-SiC boules.

Several 4H-SiC wafers sliced from semi-insulating 4H-SiC boules grown with the CeSi₂ additive subject to impurity analysis via Secondary Ion Mass Spectrometry (SIMS) to detect for the presence of Ce (the SIMS detection limit for Ce is 2×10¹³ cm⁻³. This analysis detected no Ce presence in the material bulk.

Growth Runs of Two Nominally Undoped 4H-SiC Boules.

The growth of two undoped 4H-SiC single crystal boules was carried out in the PVT growth system shown in FIG. 1. For each boule, a sublimation source 3 of 500 g of high-purity SiC grain, 0.5 to 2 mm in size was prepared. For one boule, the SiC sublimation source 3 was mixed with 3 g of the CeSi₂ additive. For the other boule, the SiC sublimation source 3 was mixed with 5 g of the CeSi₂ additive.

For each growth run, the mixture of SiC source 3 and CeSi₂ additive was disposed on the bottom of growth crucible 1. A SiC seed crystal 4 was prepared and attached to the lid 2 of crucible 1, as shown in FIG. 1. Each growth run was carried out in a helium atmosphere at a pressure of 10 Torr. Crucible 1 was then heated by RF coil 8 whereupon the temperatures of SiC seed crystal 4 and the mixture of CeSi₂ and SiC source 3 were brought to and maintained throughout the growth run at 2075° C. and 2135° C., respectively.

Wafers sliced from these as-grown boules were characterized using Raman microscopy, x-ray diffraction and selective etching. No foreign polytypes were detected in either boule.

In summary, the foregoing description describes, among other things:

1. PVT sublimation growth of SiC single crystals of stable 4H polytype which is carried out with a small amount of Ce compound, desirably silicide or carbide, added to the SiC source 3;

2. The amount of the Ce compound is desirably between 0.1% and 5% of the weight of the SiC source 3;

3. A process for sublimation growth of SiC single crystals, wherein the Ce compound is added directly to the SiC source 3;

4. A process for sublimation growth of SiC single crystals, wherein the Ce additive is contained inside a capsule separated from the SiC source 3, for instance, in a graphite capsule that has a capillary therein; and

5. The desired Ce additives are Ce silicide and Ce carbide.

The invention has been described with reference to desired embodiments. Obvious modifications and alterations will occur to those skilled in the art upon reading and understating the preceding detailed description. It is intended that the invention be construed as including all such modifications and alterations insofar as they come within the scope of the appended claims or the equivalents thereof.

The invention claimed is:

1. A SiC single crystal grown by physical vapor transport (PVT) in a graphite growth chamber, the interior of which is charged with a SiC source material and a SiC single crystal seed in spaced relation, wherein during PVT growth of the SiC single crystal the growth chamber further includes Ce and the SiC single crystal grows on the SiC single crystal seed in response to heating the interior of the growth chamber to a growth temperature and in the presence of a temperature gradient in the growth chamber whereupon the temperature of the SiC single crystal seed is lower than the temperature of the SiC source material.

2. The SiC single crystal of claim 1, further comprising either vanadium or nitrogen.

3. The SiC single crystal of claim 1, wherein the Ce is comprised of either a Ce silicide or a Ce carbide.

4. The SiC single crystal of claim 1, wherein:
the growth temperature is between 2000° C. and 2400° C.; and
the temperature gradient is between 10° C. and 200° C.

5. A physical vapor transport method of growing a SiC single crystal comprising:
(a) providing a growth chamber charged with SiC source material and a SiC single crystal seed in spaced relation;
(b) providing Ce in the growth chamber, wherein the Ce is either mixed with the SiC source material in the growth chamber or is contained in a capsule in the growth chamber, wherein the capsule has a capillary that extends between the interior thereof and the exterior thereof; and
(c) heating the SiC source material, the SiC single crystal seed and the Ce to a growth temperature whereupon a temperature gradient forms in the growth chamber that causes the SiC source material and the Ce to sublimate, the temperature gradient causes the sublimated SiC source material to be transported to the SiC single crystal seed where it precipitates on the SiC single crystal seed to form a SiC single crystal on the SiC single crystal seed.

6. The method of claim 5, wherein the sublimated Ce promotes the formation of a 4H polytype in the SiC single crystal.

7. The method of claim 5, wherein the capsule is made from graphite.

8. The method of claim 5, wherein the Ce comprises 0.1-5.0 weight percent of the SiC source material.

9. The method of claim 5, wherein:
step (c) occurs in the presence of a gas at a pressure between 1 and 200 Torr; and
the gas comprises an inert gas.

10. The method of claim 9, wherein the inert gas is either argon or helium.

11. The method of claim 9, wherein the gas further comprises nitrogen.

12. The method of claim 5, further comprising vanadium in the SiC source material.

13. The method of claim 5, wherein the Ce in step (b) is comprised of either Ce silicide or Ce carbide.

14. The method of claim 5, wherein:
the temperature gradient is between 10° C. and 200° C.; and
the growth temperature is between 2000° C. and 2400° C.
